(19) United States
(12) Patent Application Publication
(10) Pub. No.: US 2006/0148171 A1
(43) Pub. Date: Jul. 6, 2006

(54) Method of fabricating a flash memory device

(76) Inventor: Ki Min Lee, Seoul (KR)

Correspondence Address: MCKENNA LONG & ALDRIDGE LLP;Song K. Jung, 1900 K Street, N.W., Washington, NY, 20006, US

(21) Appl. No.: 11/320,780

(22) Filed: Dec. 30, 2005

(30) Foreign Application Priority Data
Dec. 31, 2004 (KR) 10-2004-118395

(51) Int. Cl. H01L 21/336

(52) U.S. Cl. 438/257

(57) ABSTRACT

A method of fabricating a flash memory device, having a double gate structure, including an oxide/nitride/oxide (ONO) layer, provides more stable operation by using a dummy pattern upon forming the ONO layer and using a control gate after forming a floating gate. The method includes steps of forming a floating gate on a semiconductor substrate; forming a dummy pattern on the floating gate; etching the floating gate using the dummy pattern as a hard mask; forming an insulating layer flush with an upper surface of the dummy pattern; removing the dummy pattern to leave a space for an ONO layer and control gate formation; and sequentially forming an ONO layer and a control gate in the space left by removing the dummy pattern.

### CROSS REFERENCE TO RELATED APPLICATIONS

This application claims the benefit of Korean Patent Application No. 10-2004-0118395, filed on Dec. 31, 2004, which is hereby incorporated by reference as if fully set forth herein.

### BACKGROUND OF THE INVENTION

1. Field of the Invention

The present invention relates to a method of fabricating a flash memory device, and more particularly, to a method of fabricating a flash memory device having a double gate structure including an oxide/nitride/oxide (ONO) layer, which has more stable operation by using a dummy pattern upon forming the ONO layer and a control gate after forming a floating gate.

2. Discussion of the Related Art

A semiconductor memory device may be classified as a read only memory (ROM) devices or a random access memory (RAM) device. While RAM devices, such as a dynamic random access memory (DRAM) or a static random access memory (SRAM), are considered non-volatile since data storage is maintained even if power is interrupted, the input/output speed (access time) of such devices is rather slow. On the other hand, ROM devices exhibit much higher input/output speeds but are volatile memory devices.

An erasable/programmable ROM (EPROM) device can be realized as a flash memory device, in which each memory cell can be electrically programmed to store one bit using one transistor and in which an entire bank of such transistors can be electrically erased in a “flash.” Thus, flash memory devices are considered electrically erasable and programmable ROM (EEPROM) devices.

A memory cell (cell transistor) of the flash memory device typically has a vertical gate structure including a floating gate of doped polysilicon and a control gate formed as a low-resistance polycide (polysilicon and a metal silicide). A multilayered gate structure includes a tunnel oxide layer and interlayer insulating layer formed on a silicon substrate, and a control gate formed on or near the floating gate. Such a memory cell is programmed by generating channel hot electrons at a drain region and accumulating electrons in the floating gate to increase the transistor's threshold voltage. The memory cell can then be erased by applying a high voltage across the substrate and the floating gate to discharge the accumulated electrons and thereby decreasing the threshold voltage. When programming and erasing the data, the floating gate functions as a tunneling source to control charge characteristics of the tunnel oxide layer. The interlayer insulating layer is typically an oxide/nitride/oxide (ONO) layer for maintaining the stored charge of the floating gate. During operation, for programming or erasing data, a voltage is applied to the control gate to move electrons from the substrate into the floating gate (programming) or from the floating gate back into the substrate (erasing).

A typical method of fabricating a flash memory device increases integration by forming a gate line of tungsten to achieve low resistance and, upon performing a post-thermal process to the tungsten gate line, forming an anti-oxidizing sealing nitride layer to inhibit oxidation of the tungsten due to the post-thermal process. Such a method is illustrated in FIGS. 1A-1E.

Referring to FIG. 1A, a first polysilicon layer 5 for a floating gate, an ONO layer 7, a second polysilicon layer 9 for a control gate, a tungsten layer 11, and a hard-mask nitride layer 13 are sequentially deposited on a cell region of a silicon substrate 1. The second polysilicon layer 9 is etched to form a gate line (not shown) as well as the control gate. Then, an anti-oxidizing sealing nitride layer 15 is formed on the silicon substrate 1, including on the upper and side surfaces of the nitride layer 13. A selective oxide layer 8 serves to protect side surfaces of the control gate. The above layers, except for the first polysilicon layer 5 and the ONO layer 7, are correspondingly formed on a periphery region of the silicon substrate 1.

Referring to FIG. 1B, the anti-oxidizing sealing nitride layer 15 is anisotropically etched to form an oxide sealing nitride layer pattern 15a, having a spacer shape, covering the sidewalls of an upper portion of the multilayered gate structure.

Referring to FIG. 1C, the periphery region is covered with a photoresist pattern 17. Thus, a first polysilicon layer pattern 5a and an ONO layer pattern 7a are formed by etching the cell region of the first polysilicon layer 5 and the ONO layer 7 to expose the surface of the tunnel oxide layer 3. At this time, some incidental over-etching may occur laterally, such that, after etching, the exposed sides of the first polysilicon layer 5 and the ONO layer 7 are partially recessed inward beyond the depth of the oxide sealing nitride layer pattern 15a. In addition, after the etching process, a source/drain region (not shown) is formed by implanting ions, such as boron or arsenic, into the exposed surfaces of the cell region.

Referring to FIG. 1D, a post-thermal process is performed to grow oxide layers 19a and 19b in the cell region of the substrate 1.

Referring to FIG. 1E, a nitride layer for spacer formation is deposited on the overall structure and is etched back to form a spacer 21. Subsequent processing is then performed to complete the flash memory device.

In the above method, however, if the exposed side surfaces of the ONO layer pattern 7a are over-etched, the electrons stored in the floating gate (5a) are provided a path to move into the control gate (9), thereby deteriorating the memory function of the flash memory device and causing an operational instability. Also, as shown in FIG. 2, a shallow-trench isolation (STI) recess may be generated in the shallow-trench isolation layer. These undesirable phenomena are especially problematic if the ONO layer is etched using a fluorine gas such as CF₄.

### SUMMARY OF THE INVENTION

Accordingly, the present invention is directed to a method of fabricating a flash memory device that substantially obviates one or more problems due to limitations and disadvantages of the related art.

An advantage of the present invention is that it can provide a method of fabricating a flash memory device, which improves the isolation between the floating gate and the control gate by patterning the control gate and an ONO layer after sequentially forming a dummy pattern, a source/drain region, a spacer, and an insulating layer.

Another advantage of the present invention is that it can provide a method of fabricating a flash memory device, which prevents over-etching and recessing phenomena caused during an etching process performed with respect to the ONO layer using a fluorine gas (e.g., CF₄), to thereby enable an increased process margin.

Additional features and advantages of the present invention will be set forth in part in the description which follows, and in part will become apparent from the description, or may be learned by practice of the invention. These and other advantages of the invention may be realized and attained by the structure particularly pointed out in the written description and claims hereof as well as the appended drawings.

To achieve these and other advantages in accordance with the purpose of the invention, as embodied and broadly described herein, a method of fabricating a flash memory device comprises forming a floating gate on a semiconductor substrate; forming a dummy pattern on the floating gate; etching the floating gate using the dummy pattern as a hard mask; forming an insulating layer flush with an upper surface of the dummy pattern; removing the dummy pattern to leave a space for an ONO layer and control gate formation; and sequentially forming an ONO layer and a control gate in the space left by removing the dummy pattern.

It is to be understood that both the foregoing general description and the following detailed description of the present invention are exemplary and explanatory and are intended to provide further explanation of the invention as claimed.

### BRIEF DESCRIPTION OF THE DRAWINGS

The accompanying drawings, which are included to provide a further understanding of the invention and are incorporated in and constitute a part of this specification, illustrate embodiment(s) of the invention and together with the description serve to explain the principle of the invention.

In the drawings:

FIGS. 1A-1E are cross-sectional views of a contemporary flash memory device, respectively illustrating sequential process steps of a fabrication method according to the related art; and

FIG. 2 is a different cross-sectional view of the flash memory device fabricated according to the method shown in FIGS. 1A-1E.

FIGS. 3A-3H are cross-sectional views of a flash memory device, respectively illustrating sequential process steps of a method for fabricating the device according to an exemplary embodiment of the present invention.

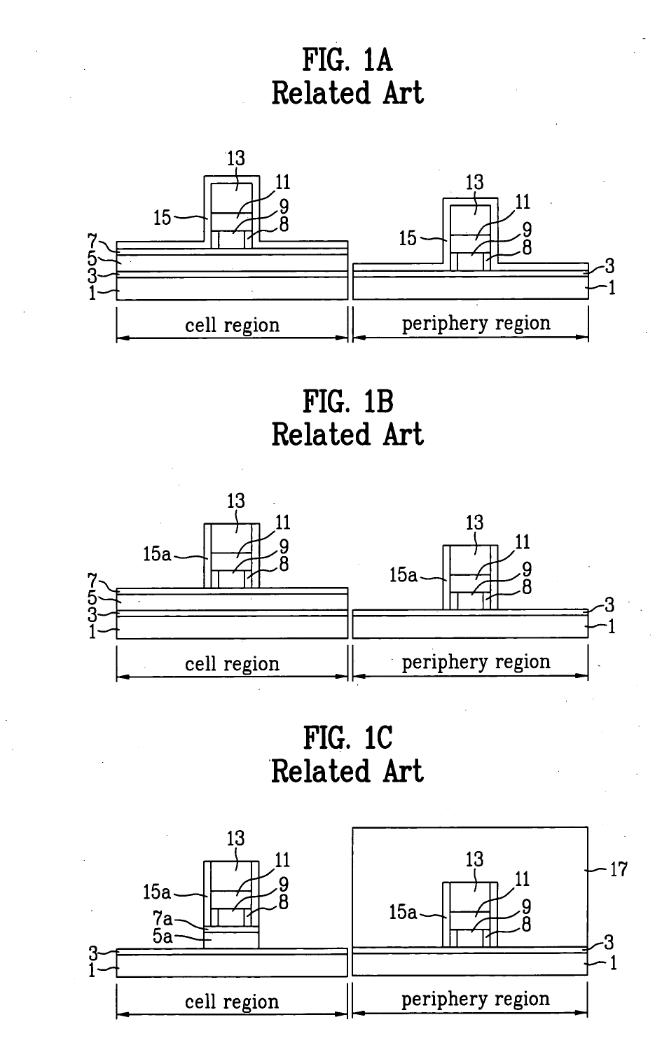

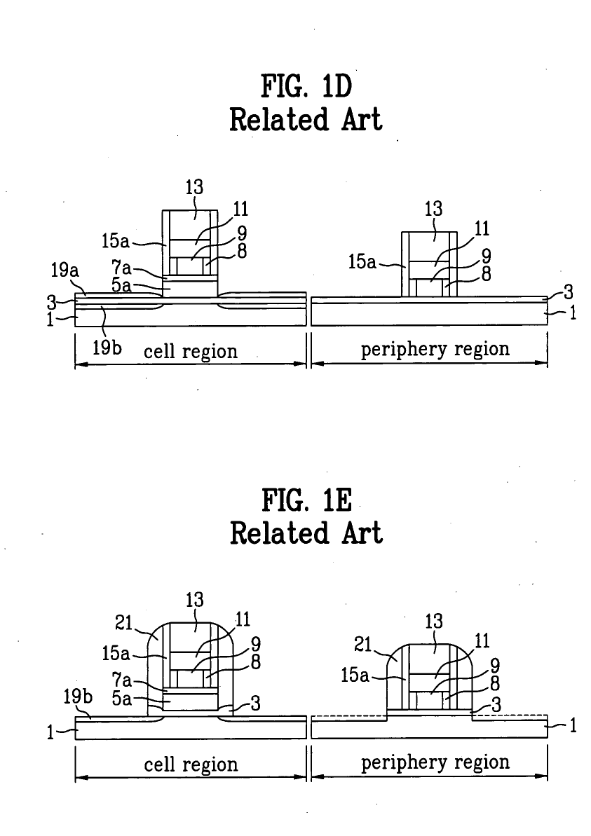

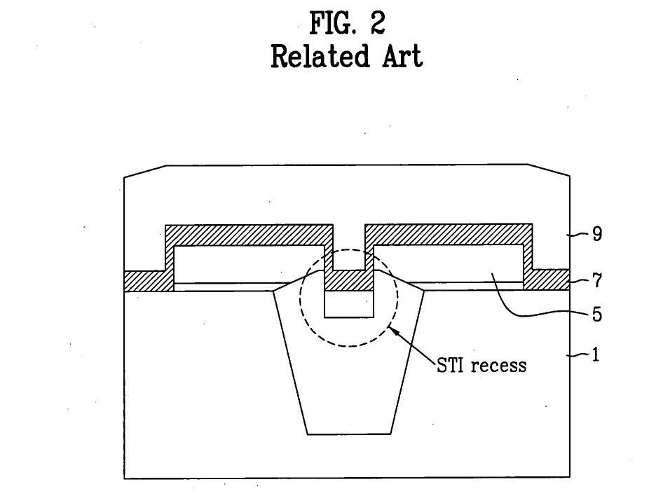

### DETAILED DESCRIPTION OF THE INVENTION

Reference will now be made in detail to exemplary embodiments of the present invention, examples of which are illustrated in the accompanying drawings. Wherever possible, like reference designations will be used throughout the drawings to refer to the same or similar parts.

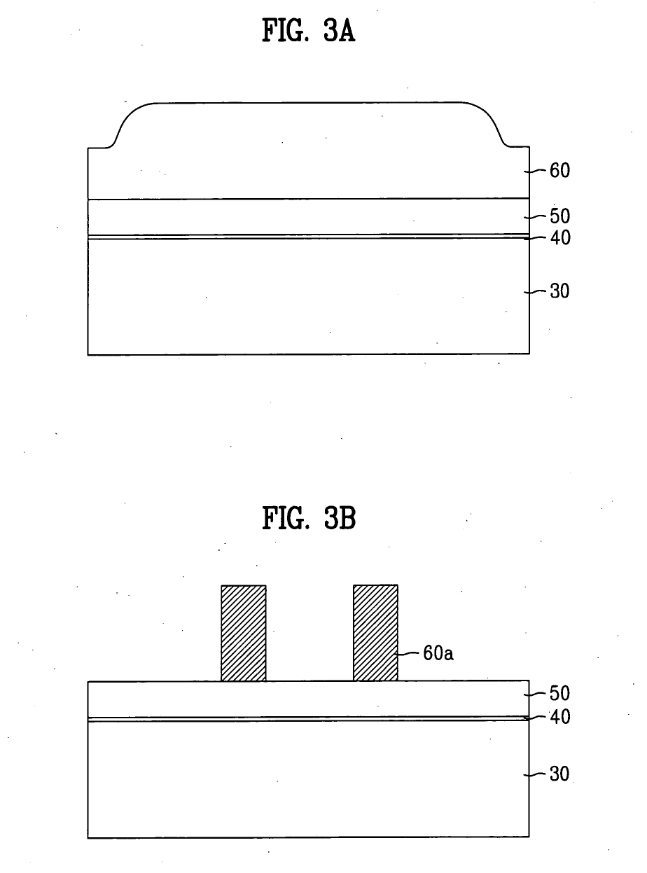

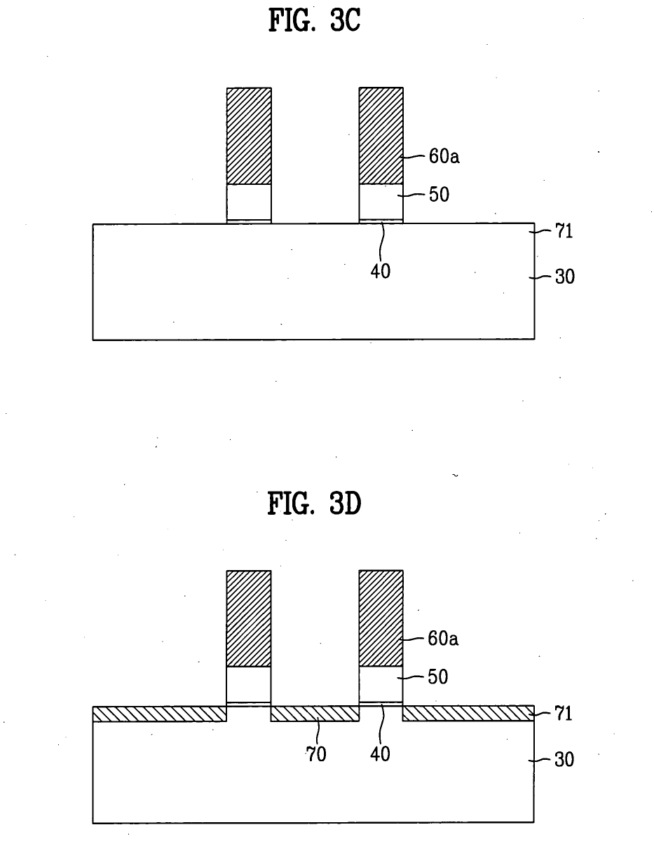

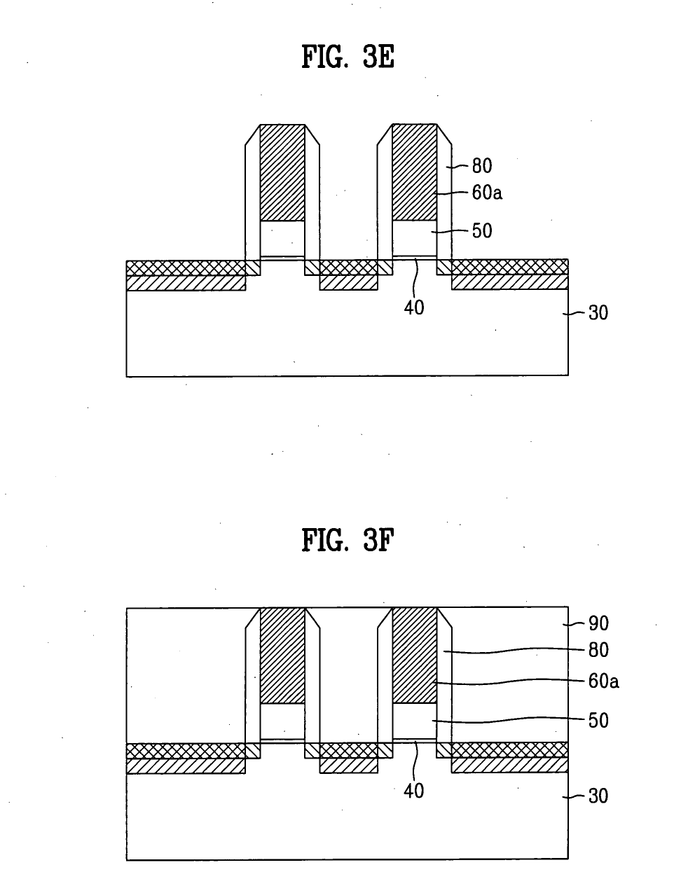

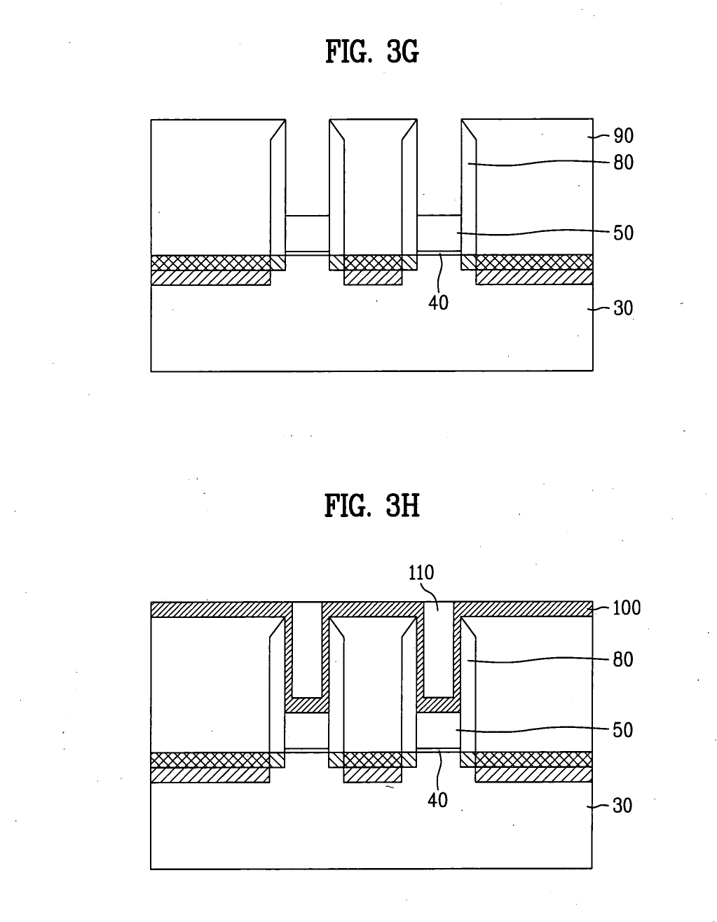

Referring to FIG. 3A, a tunnel oxide layer 40 and a floating gate 50 are sequentially formed on a semiconductor substrate 30. A silicon nitride layer 60 for dummy pattern formation is deposited on the floating gate 50.

Referring to FIG. 3B, the silicon nitride layer 60 is exposed and etched to form the dummy pattern 60a by photolithography. The silicon nitride layer 60 selectively is etched using a CHₓF_{y} gas, for example, CH₃F or CH₂F₂.

Referring to FIG. 3C, the floating gate 50 is etched using the dummy pattern 60a as a hard mask.

Referring to FIG. 3D, a source region 70 and a drain region 71 are formed by ion implantation. The source/drain regions 70 and 71 are formed in an exposed surface of the semiconductor substrate 30 using the etched floating gate as a mask.

Referring to FIG. 3E, a nitride layer may be formed and etched to form a spacer 80. The spacer 80 is formed on sidewalls of the floating gate 50 and the dummy pattern 60a so that the source/drain regions may be deepened by an additional ion implantation step using the sidewall spacers as a mask.

Referring to FIG. 3F, an insulating layer is formed using a tetra-ethyl-ortho-silicate (TEOS) oxide layer 90 and is planarized until flush with the upper surface of the dummy pattern 60a.

Referring to FIG. 3G, the dummy pattern 60a is removed by performing an etching process using NH₄OH at a high temperature.

Referring to FIG. 3H, an ONO layer 100 and a control gate 110 are sequentially formed in the space in which the dummy pattern 60a is removed. Accordingly, complete isolation between the floating gate 50 and the control gate 110 can be obtained.

According to the present invention, since an ONO layer and a control gate are formed after forming a dummy pattern, a source/drain region, a spacer, and an insulating layer, an improved (more perfect) isolation between the floating gate and control gate of a flash memory device can be obtained by avoiding an over-etching phenomenon with respect to the floating gate or the ONO layer. Furthermore, recessing with respect to a shallow-trench isolation layer, due to the use of a fluorine etching gas for etching the ONO layer, can be prevented so that a process margin can be increased.

It will be apparent to those skilled in the art that various modifications and variations can be made in the present invention without departing from the spirit or scope of the invention. Thus, it is intended that the present invention covers such modifications and variations provided they come within the scope of the appended claims and their equivalents.

What is claimed is:

1. A method of fabricating a flash memory device, comprising:
forming a floating gate on a semiconductor substrate;
forming a dummy pattern on the floating gate;
etching the floating gate using the dummy pattern as a hard mask;
forming an insulating layer flush with an upper surface of the dummy pattern;
removing the dummy pattern to leave a space for an ONO layer and control gate formation; and
sequentially forming an ONO layer and a control gate in the space left by removing the dummy pattern.

2. The method according to claim 1, further comprising:
forming a spacer on sidewalls of the floating gate and the dummy pattern

3. The method according to claim 2, further comprising:
forming a source/drain region in an exposed surface of the semiconductor substrate using the etched floating gate and the sidewall spacers as a mask.

4. The method according to claim 1, wherein the insulating layer is made flush with the upper surface of the dummy pattern by planarization.

5. The method according to claim 1, wherein the dummy pattern is formed of silicon nitride.

6. The method according to claim 1, wherein the dummy pattern is formed by photolithography and etching processes.

7. The method according to claim 6, wherein the etching process uses CHₓF_{y} gas.

8. The method according to claim 7, wherein the CHₓF_{y} gas is one of CH₃F and CH₂F₂.

9. The method according to claim 1, wherein the insulating layer is a TEOS oxide layer.

10. The method according to claim 1, wherein the dummy pattern is removed using NH₄OH at a high temperature.
